(19) United States
(12) Patent Application Publication
(10) Pub. No.: US 2007/0108451 A1
(43) Pub. Date: May 17, 2007

(54) Image forming apparatus

(76) Inventors: Hirotaka Unno, Fukaya-shi (JP); Akiyoshi Yamada, Fukaya-shi (JP); Tsukasa Ooshima, Takasaki-shi (JP)

Correspondence Address: OBLON, SPIVAK, MCCLELLAND, MAIER & NEUSTADT, P.C., 1940 DUKE STREET, ALEXANDRIA, VA, 22314, US

(21) Appl. No.: 11/506,777

(22) Filed: Aug. 21, 2006

Related U.S. Application Data
(63) Continuation of application No. PCT/JP05/03338, filed on Feb. 28, 2005.

(30) Foreign Application Priority Data
Mar. 2, 2004 (JP) 2004-057924

(51) Int. Cl. H01L 33/00; H01L 31/12; H01L 27/15; H01L 29/26

(52) U.S. Cl. 257/79

(57) ABSTRACT

On the peripheral edge of a front side substrate of an FED, a rectangular frame shaped sealing surface is formed for sealing a sidewall. On the sealing surface, an indium layer is formed through a base layer. At the four corners of the indium layer, an electrode for applying an electric current is connected. The indium layer is formed to have a width gradually decreasing from substantially the center of each side of the sealing surface to adjacent corners.

### CROSS-REFERENCE TO RELATED APPLICATIONS

This is a Continuation Application of PCT Application No. PCT/JP2005/003338, filed Feb. 28, 2005, which was published under PCT Article 21(2) in Japanese.

This application is based upon and claims the benefit of priority from prior Japanese Patent Application No. 2004-057924, filed Mar. 2, 2004, the entire contents of which are incorporated herein by reference.

### BACKGROUND OF THE INVENTION

1. Field of the Invention

The present invention relates to a method of manufacturing an image forming apparatus comprising a rear side substrate having a number of electron emitting elements and a front side substrate having a fluorescent screen, which are opposed to each other and sealed in the peripheral edges.

2. Description of the Related Art As a next-generation light and thin plane image display unit, an image display unit (hereinafter called an FED) using a field emission type electron emitting element (hereinafter called an emitter) or an image display unit (hereinafter called an SED) using a surface transmission emitter has been known in recent years.

For example, an FED generally has a front side substrate and a rear side substrate opposed with a certain clearance. These substrates are connected in the peripheral edges through a rectangular frame-like sidewall. A fluorescent screen is formed on the inner surface of the front side substrate, and a number of emitters to excite and light a fluorescent substance are provided as an electron emission source on the inside surface of the rear side substrate. A plurality of support member is provided between these substrates to support an atmospheric load applied to the front and rear side substrates.

The rear side substrate has a potential of almost zero, and an anode voltage Va is applied to the fluorescent screen. Electron beams emitted from the emitters are applied to red, green and blue fluorescent substances constituting the fluorescent screen, and an image is displayed by lighting the fluorescent substances.

In the above FED, a clearance between the front and rear side substrates can be set to several millimeters or less. This realizes reduction of thickness and weight, compared with a cathode-ray tube (CRT) used now as a display of a television and a computer.

In such an image display unit, a method of sealing the peripheral edges of front and rear side substrates by using a metallic material such as indium with a low melting point has been developed (e.g., Jpn. Pat. Appln. KOKAI Publication No. 2002-319346). According to this method, indium is applied all around the sealing surface of the substrate peripheral edges, the indium is fused by electrically heating in a vacuum, and a vacuum enclosure is assembled by sealing the peripheral edges of front and rear side substrates. This can quickly seal the substrates without heating unnecessarily while keeping the inside of the enclosure an ultrahigh vacuum.

However, as the thickness of applied indium is uniform in this method, quick vacuum sealing by the above-mentioned electrical heating is possible when no unevenly heated points occur on all over the substrate. But, the indium applied to four sides of the sealing surface tends to melt first and the indium applied close to the four corners tends to melt later. This causes a problem that the indium exudes in the sides, and causes a short in the wiring on the substrate.

Namely, as the substrate is rectangular, heat escapes largely at the corners even if the substrate is uniformly heated, and the temperature at a corner tends to be lower than that at a side. Further, after passing through a baking process, the indium melts and flows into the corners, and the thickness of indium tends to be thicker at the corners than the sides. Thus, larger energy is required to fuse the indium at the corners where the temperature is low and the indium is thick, compared with the sides where the temperature is high and the indium is thin.

Namely, the indium at the corners is not fused by the above electric heating, the indium does not flow out of the corners, and the vacuum enclosure becomes thick at the corners. Further, if the heating is continued to fuse sufficiently the indium at the corners, extra energy is supplied to sides and the indium at the sides is broken. The difference in the indium fusing time makes quick vacuum sealing difficult, nullifying to the purpose of the electrical heating. Further, the indium at the corners melts last, and the indium melted first at the sides loses an escape and overflows to the substrate, causing a short in the wiring on the substrate.

### BRIEF SUMMARY OF THE INVENTION

The invention has been made to solve the above problems. It is an object of the invention to provide an image display unit capable of sealing the peripheral edges of a rear side substrate and a front side substrate securely and easily without heating unnecessarily.

In order to achieve the above object, according to the invention, there is provided an image display unit comprising: a vacuum enclosure having a rear side substrate and a front side substrate which are opposed to each other and sealed in the peripheral edges by a sealing agent fused by an electric current; and a plurality of image display elements provided inside the vacuum enclosure, wherein the fusing agent is applied all around a circular sealing surface at the peripheral edge between the rear side substrate and front side substrate, an electrode for applying an electric current is connected, and the width of the part connected to the electrode is less than the widths of the other parts.

The image display unit of the invention comprises: a vacuum enclosure having a rear side substrate and a front side substrate which are opposed to each other and sealed in the peripheral edges by a sealing agent fused by an electric current; and a plurality of image display elements provided inside the vacuum enclosure, wherein the fusing agent is applied all around a circular sealing surface at the peripheral edge between the rear side substrate and front side substrate, an electrode for applying an electric current is connected, and the cross section of the part connected to the electrode is narrower than the cross sections of the other parts.

The image display unit of the invention comprises: a vacuum enclosure having a rear side substrate and a front side substrate which are opposed to each other and sealed in the peripheral edges by a sealing agent fused by an electric current; a fluorescent screen which is formed on the inner surface of the front side substrate; an electron emission source which is provided on the inner surface of the rear side substrate, emits an electron beam to the fluorescent screen, and lights the fluorescent screen, wherein the fusing agent is applied all around a circular sealing surface at the peripheral edge between the rear side substrate and front side substrate, an electrode for applying an electric current is connected to at least two locations, and the width of the part connected to the electrode is less than the widths of the other parts.

According to the invention, a fusing agent is fused first in a part connected with an electrode and later in the other parts separated from that part, and a sealing agent fusing order is controlled.

The image display unit of the invention comprises a vacuum enclosure having a rear side substrate and a front side substrate which are opposed to each other and sealed in the peripheral edges by a sealing agent, and a plurality of image display element provided inside the vacuum enclosure, wherein the fusing agent is applied all around a circular sealing surface at the peripheral edge between the rear side substrate and front side substrate, and the cross section of fusing agent at a corner of the sealing surface is smaller than that in the other parts.

The image display unit of the invention comprises a vacuum enclosure having a rear side substrate and a front side substrate which are opposed to each other and sealed in the peripheral edges by a sealing agent, and a plurality of image display element provided inside the vacuum enclosure, wherein the fusing agent is applied all around a circular sealing surface at the peripheral edge between the rear side substrate and front side substrate, and the width of fusing agent at a corner of the sealing surface is less than that in the other parts.

### BRIEF DESCRIPTION OF THE SEVERAL VIEWS OF THE DRAWING

FIG. 1 is an external perspective view of FED according to an embodiment of the invention;

FIG. 2 is a sectional view taken along lines A-A of FIG. 1;

FIG. 3 is a partially plane view showing a fluorescent screen of the FED;

FIG. 4 is a plane view showing the state that an indium layer is formed on the sealing surface of a front side substrate constituting a vacuum enclosure of the FED;

FIG. 5 is a partially sectional view showing the state that a rear side substrate assembly is opposed to the front side substrate with the indium layer formed on the sealing surface;

FIG. 6 is a schematic diagram of a vacuum processor used for manufacturing the FED;

FIG. 7 is an image showing a modification of an indium layer of FIG. 4;

FIG. 8 is an image showing another modification of an indium layer of FIG. 4; and

FIG. 9 is an image showing still another modification of an indium layer of FIG. 4.

### DETAILED DESCRIPTION OF THE INVENTION

Hereinafter description will be given on embodiments of an image display unit of the present invention applied to an FED with reference to the accompanying drawings.

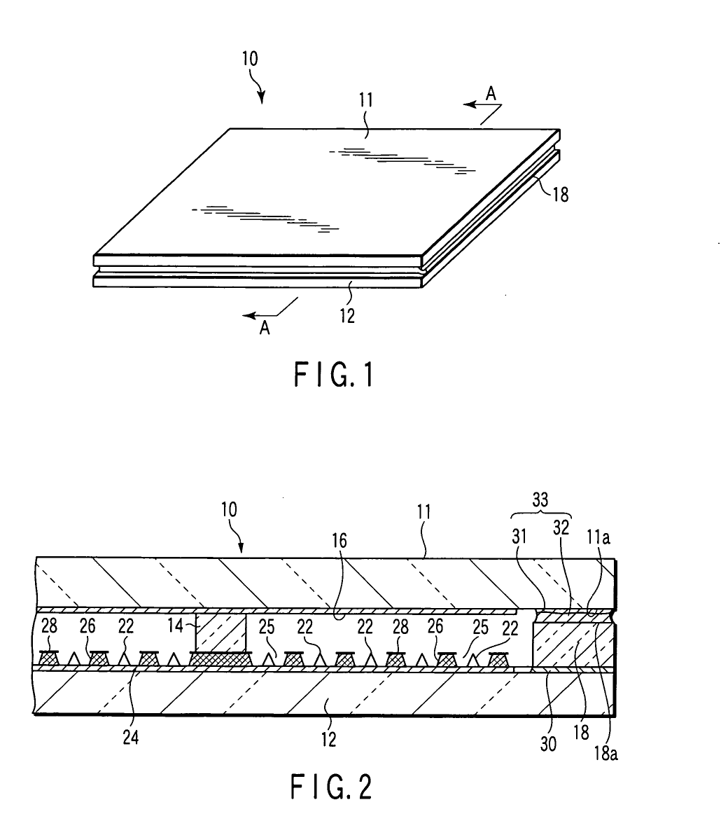

As shown in FIG. 1 and FIG. 2, the FED comprises a front side substrate 11 and a rear side substrate 12, which are provided with a rectangular glass as a base material and opposed to each other with a clearance of 1.5-3.0 mm. The front side substrate 11 and rear side substrate 12 are sealed in the peripheral edges through a rectangular frame-like sidewall 18, forming a flat rectangular vacuum enclosure kept at a vacuum inside.

As described later, a sealing surface between the rear side substrate 12 and sidewall 18 is sealed by a glass 30 with a low melting point, such as a flit glass. A clearance between the front side substrate 11 and sidewall 18 is sealed by a base layer 31 formed on the sealing surface and a sealing layer 33 fused into an indium layer 32 (a sealing agent) formed on the base layer.

A plurality of support member 14 is provided inside the vacuum enclosure 10 to support an atmospheric load applied to the front side substrate 11 and rear side substrate 12. These support members 14 are extended in the direction parallel to the long side of the vacuum enclosure 10 and placed with a predetermined clearance along the direction parallel to the short side. The shape of the support member 14 is not limited to this, and a column-shaped support member may be used.

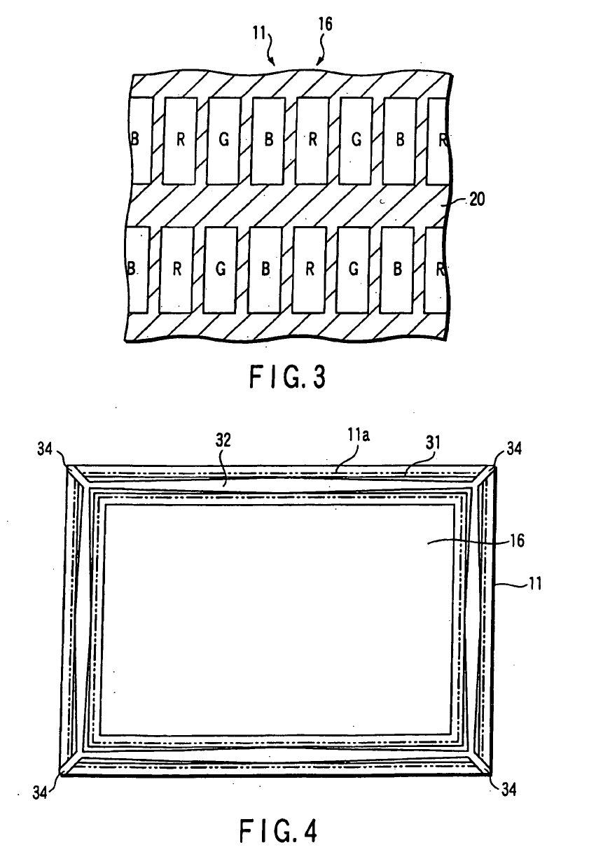

As shown in FIG. 3, a fluorescent screen 16 is formed on the inner surface of the front side substrate 11. The fluorescent screen 16 is composed of fluorescent substance layers R, G and B to light in red, green and blue colors, and a matrix black color absorbing part 20. The support members 14 are placed just like hidden by the shade of the black color absorbing part. On the fluorescent screen 16, a not-shown aluminum layer is evaporated as a metal back.

As shown in FIG. 2, on the inside surface of the rear side substrate 12, a number of field emission type electron emitting elements 22 to emit an electron beam are provided as an electron emitting source to excite the fluorescent substance layers R, G and B. These electron emitting elements 22 are arranged in rows and columns corresponding to each pixel, and function as a pixel displaying element.

Describing in details, a conductive cathode layer 24 is formed on the inner surface of the rear side substrate 12, and a silicon dioxide film 26 having many cavities 25 is formed on the conductive cathode layer. On the silicon dioxide film 26, a gate electrode 28 composed of molybdenum or niobium is formed. A cone-shaped electron emitting element 22 composed of molybdenum is provided in each cavity 25 on the inner surface of the rear side substrate 12. Further, a not-shown wiring matrix connected to the electron emitting element 22 is formed on the rear side substrate 12.

In the FED configured as described above, a video signal is input to the electron emitting element 22 and gate electrode 28 formed as a simple matrix system. Regarding the electron emitting element 22 as a basis, a gate voltage of +100 V is applied when the luminance is highest. A voltage of +10 kV is applied to the fluorescent screen 16. The magnitude of the electron beam emitted from the electron emitting element 22 is modulated by the voltage of the gate electrode 28. The modulated electron beam excites and lights the fluorescent substance layer of the fluorescent screen 16, and an image is displayed.

Detailed description will now be given on a method of manufacturing the FED configured as described above.

First, create a fluorescent screen 16 on a plate glass, which is to be used as the front side substrate 11. Prepare a plate glass of the same size as the front side substrate 11, and form a stripe pattern of a fluorescent substance layer on the plate glass by a plotter machine. Place the plate glass with the plotted fluorescent stripe pattern and a plate glass for the front side substrate on a positioning jig, and set them on an exposure table. Expose and develop the pattern, and creates the fluorescent screen 16.

Then, create the electron emitting element 22 on a plate glass for a rear side substrate. Create a conductive cathode layer matrix on the plate glass, and form an insulating film of silicon dioxide by thermal oxidation, CVD or spattering.

Form a metallic film of molybdenum or niobium for a gate electrode on the insulating film by spattering or electron beam evaporation. Form a resist pattern corresponding to a forming gate electrode on the metallic film by lithography. Etch the metallic film through the resist pattern as a mask by wet or dry etching, and form the gate electrode 28.

Etch the insulation film through the resist pattern and gate electrode as a mask by wet or dry etching, and form the cavity 25. After removing the resist pattern, perform electron beam evaporation on the surface of the rear plate from the direction inclined by a predetermined angle, and form a stripping layer of aluminum, nickel or cobalt on the gate electrode 28. Evaporate molybdenum as a material for a cathode on the surface of the rear side substrate by electron beam evaporation from a direction vertical to the surface of the rear side substrate. Thereby, form the electron emitting element 22 in each cavity 25. Remove the stripping layer together with the metallic film formed thereon by a lift-off method.

Then, seal the sealing surface between the peripheral edge of the rear side substrate 12 with the electron emitting element 22 and the rectangular frame-like sidewall 18 in the atmosphere by the glass 30 with a low melting point. At the same time, seal the support members 14 on the rear plate 12 in the atmosphere by the glass 30 with a low melting point.

Seal the rear plate 12 and front plate 11 through the sidewall 18. In this case, as shown in FIG. 4, first form the base layer 31 all over the inside peripheral edge, which will become a sealing surface 11a of the front side substrate 11. The sealing surface 11a is shaped rectangular corresponding to the upper surface of the sidewall 18, which will become a sealing surface 18a of the rear side substrate 12, and extended along the inside peripheral edge of the front side substrate 11. The sealing surface 11a has two pairs of linear parts opposite to each other, or four sides and four corners, and has substantially the same size and width as those of the upper surface of the sidewall 18. The width of the base layer 31 is made slightly less than the width of the sealing surface 11a. In this embodiment, the base layer 31 is formed by applying silver paste.

Apply indium as a sealing agent composed of a metal with a low melting point, on the base layer 31, and form the indium layer 32 extending continuously without a break all over the periphery of the base layer 31. In this case, form the indium layer 32 for each of the four sides of the sealing surface 11a to have a cross section gradually decreasing from substantially the center of a side to adjacent corners. Connect the electrode 34 to the indium layer 32 at each of the four corners. The indium layer 32 should be formed within the width of the base layer 31.

The indium layer 32 is not limited to the above shape, and may be others as long as the cross section of indium at a corner is smaller than that of the other parts. The position of the electrode 34 is not limited to a corner, and may be connected to a side. In this case, it is desirable to make the cross section of indium in a part connected to the electrode 34 smaller than that in the other parts.

As described above, by making the cross section of the indium layer 32 at the four corners connected to the electrode 34 smaller than that in the other parts, when the indium layer 32 is electrically fused through the electrode 34, the indium layer 32 at a corner having the relatively small cross section is fused faster than that in the other parts, and the indium layer 32 at substantially the center of a side having a relatively large cross section is fused last. Namely, by controlling the cross section of the indium layer 32, the fusing order of the indium layer 32 can be controlled to the above order. Therefore, the fused indium is escaped first through the electrode 34 connected to a corner, and the fused indium does not exude from a side. This prevents a short in the wiring on the rear side substrate 12, and ensures and facilitates sealing of the sealing surface 18a of the sidewall 18 and the sealing surface 11a of the front side substrate 11.

In this embodiment, after the indium layer 32 is formed on the sealing surface 11a, a baking process described later is taken place before electrically heating the indium and sealing the front side substrate 11 and sidewall 18, and the indium layer 32 formed on the sealing surface 11a is fused. Therefore, in this embodiment, the indium layer 32 is formed to have a width gradually decreasing from substantially the center of each side of the sealing surface a to adjacent corners, thereby changing the cross section of the indium layer 32. Namely, when the indium layer 32 is fused, the indium tends to concentrate on a widely applied part. By controlling the width of the indium layer 32, the cross section of the indium layer 32 at substantially the center of a side can be larger than that at a corner.

Concretely, in this embodiment, a widest part close to substantially the center of each side is set to 2.0 mm, and the width of the indium layer 32 is gradually changed to have a width of 1.8 mm in a narrowest part close to a corner. Namely, in this embodiment, the width of the indium layer 32 is gradually changed, so that the width of the indium layer 32 at a corner of the sealing surface 11a becomes 90% of the width at substantially the center of a side.

If the radio of the width of the indium layer 32 at a corner to a center of a side is too large, heating of the indium layer 32 is increased close to a corner, the difference in indium fusing time is increased between a corner and a side, and the indium layer 32 may be broken close to a corner at worst. Contrarily, if the radio of the width of the indium layer 32 at a corner to a center of a side is too small, the indium layer 32 becomes thick close to a corner as described above, the indium is fused first in a side, and the indium may exude from the center of a side. According to experiments, when the ratio of the width at a corner to a side is set to 50-98%, such a defect does not occur.

Indium is used as a sealing agent herein, but metals with a low melting point, such as Ga, Bi, Sn, Pb and Sb or an alloy of these metals may also be used.

Although the term “melting point” is used in the above description, a melting point may not be fixed to one in an alloy consisting of two or more metals. In such a case, a liquidus temperature and a solidus temperature are defined. The former is a temperature that a part of alloy begins to solidify when a temperature is gradually decreased from a liquid state, and the latter is a temperature that all alloys are solidified. In this embodiment, the term “melting point” is used even in these cases for explanation convenience, and the solidus temperature is called a melting point.

Contrarily, the base layer 31 is made of material with high wettability and hermeticity for a metal sealing agent, or material with high affinity for a metal sealing agent. In addition to the above-mentioned silver paste, metal paste of gold, aluminum, nickel, cobalt and copper may be used. Other than a metal paste, the base layer 31 may be formed by a metal plated layer of silver, gold, aluminum, nickel and cobalt, or an evaporated film or a glass material layer.

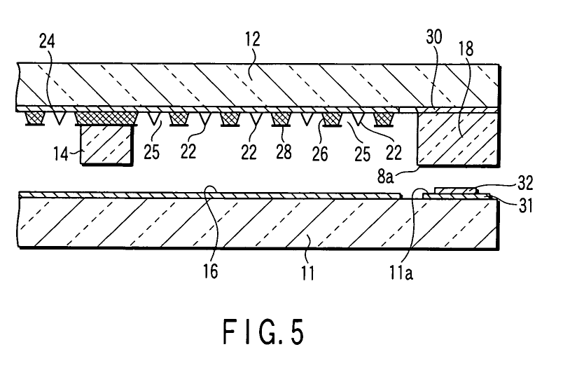

Then, as shown in FIG. 5, hold the front side substrate 11 with the base layer 31 and indium layer 32 formed on the sealing surface 11a, and the rear side assembly with the sidewall 18 sealed to the rear side substrate 12, in the state that the sealing surfaces 11a and 18a are opposed with a certain distance, by a jig, and put them into a vacuum processor.

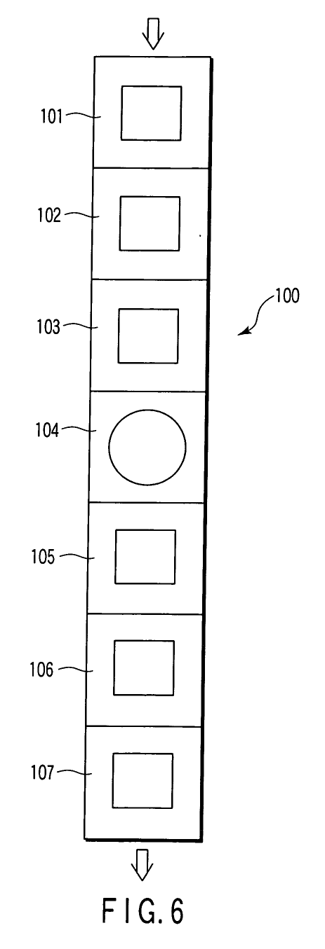

As shown in FIG. 6, the vacuum processor 100 has a loading chamber 101, a baking, electron beam cleaning chamber 102, a cooling chamber 103, a getter film evaporating chamber 104, an assembling chamber 105, a cooling chamber 106, and an unloading chamber 107, which are arranged in a line. Each of these chambers is configured as a processing chamber capable of vacuum processing, and all chambers are exhausted vacuum during a step of manufacturing of FED. Adjacent chambers are connected by a not-shown gate valve.

The rear side assembly and front side substrate 11 opposed with a certain clearance are put into the loading chamber 101 to make the inside of the loading chamber in the vacuum atmosphere, and then sent to the baking, electron beam cleaning chamber 102. In the baking, electron beam cleaning chamber 102, when a high vacuum of 10⁻⁵ Pa is attained, the rear side assembly and front side substrate are heated and baked at a temperature of approximately 300° C., to emit the surface absorption gas of each member sufficiently.

The indium layer (with a melting point of approximately 156° C.) is fused at this temperature. As described before, the indium layer 32 is formed to have a width gradually decreasing from substantially the center of each side of the sealing surface 10a to adjacent corners, and even if fused, the indium is collected in a wide part at substantially the center of each side, and the cross section of the indium at a corner becomes smaller than the other parts. At the same time, as the indium layer 32 is formed on the base layer 31 with high affinity, the fused indium is held on the base layer 31 without flowing, and prevented from flowing to the electron emitting element 22, the outside of the rear side substrate, or the fluorescent screen 16.

In the baking, electron beam cleaning chamber 102, simultaneously with heating, a not-shown electron beam generator provided in the chamber 102 emits an electron beam to the fluorescent screen surface of the front side substrate 11, and the surface of the electron emitting element of the rear side substrate 12. The electron beam is deflected and scanned by a deflector provided outside the electron beam generator, and the whole surfaces of the fluorescent screen and electron emitting element can be cleaned by the electron beams.

After heating and electron beam cleaning, the rear side substrate assembly and front side substrate 11 are sent to the cooling chamber 103, and cooled to a temperature of approximately 100° C. Then, the rear side substrate assembly and front side substrate 11 are sent to the getter film evaporating chamber 104, and a Ba film is evaporated as a getter film on the outside of the fluorescent screen. The Ba film surface is not stained by oxygen or carbon, and kept active.

Then, the rear side substrate assembly and front side substrate 11 are sent to the assembling chamber 105, in which the indium layer 32 is electrically heated through four electrodes 34 and the indium layer 32 is fused or softened again to a liquid state. As the indium layer 32 is formed to have a width gradually decreasing from substantially the center of each side to adjacent corners, the indium is fused first at a corner with a small cross section and gradually fused toward the center of a side. By controlling the order of fusing indium as described above, the indium in a side is fused while allowing the flow-out of indium from a corner, and the indium fused at substantially the center of side is prevented from exuding.

Connect and press the front side substrate 11 and sidewall 18 by a predetermined pressure in this state, and cool and solidify the indium. The sealing surface 11a of the front side substrate 11 and the sealing surface 18a of the sidewall 18 are sealed by the indium layer 32 and the sealing layer 33 fused into the base layer 31, and the vacuum enclosure 10 is formed.

The vacuum enclosure formed as above is cooled to room temperature in the cooling chamber 106, and taken out from the unloading chamber 107. The FED is completed by the above process.

As described above, according to this embodiment, the front side substrate 11 is sealed by forming the indium layer 32 on the sealing surface 11a of the front side substrate 11, and fusing the indium layer 32 by heating electrically. The front side substrate 11 and rear side substrate 12 can be sealed without heating unnecessarily. Particularly, in this embodiment, the indium layer 32 is formed to have a width gradually decreasing from substantially the center of each side of the rectangular frame-like sealing surface 11a to adjacent corners. Therefore, when the indium layer 32 is electrically heated and fused, the indium close to four corners can be fused first, the fused indium is prevented from exuding from the central area of each side, and the front side substrate 11 can be easily and securely sealed to the sidewall 18.

The invention is not limited to the above embodiments, and may be embodied by modifying the components without departing from its spirit and essential characteristics. The invention may be embodied in other specific forms by combining the components disclosed in the above embodiments. For example, some components may be deleted from the components disclosed in the above embodiments. Components of different embodiments may be combined.

For example, in the above embodiments, the indium layer 32 is formed on the base layer 31 by changing the width as described herein. The indium layer may be formed previously all over the base layer 31, and the peripheral edge may be trimmed to change the width. In any way, the indium layer may be shaped so that the width of the part connected with the electrode 34 is narrower than the widths of the other parts.

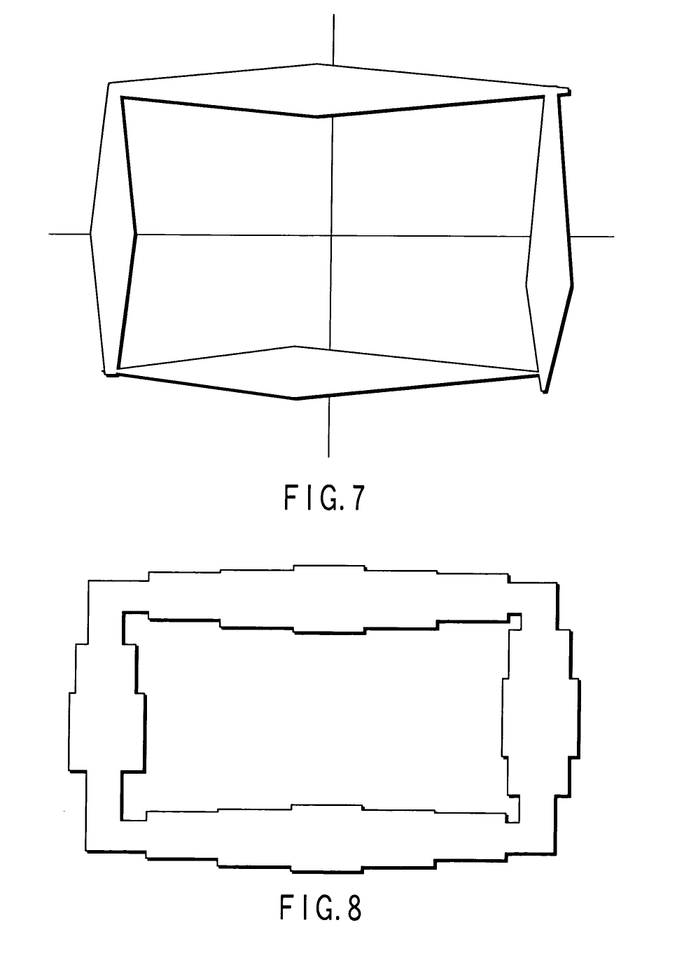

For example, in the above embodiments, the indium layer 32 is formed to have a width gradually decreasing from substantially the center of each side of the sealing surface 11a to adjacent corners. As shown in FIG. 7, the indium layer 32 may be formed to have a maximum width at the position displaced from the center of each side. Concretely, the indium layer may be formed to have a maximum width at a position separated over 30% from a corner with respect to the total length of each side.

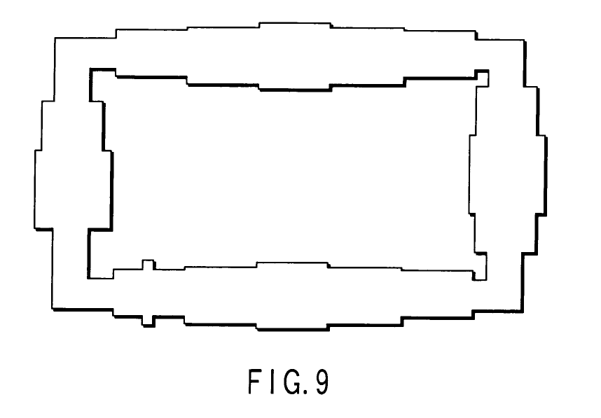

Further, in the above embodiments, the width of the indium layer 32 is continuously changed. The width of the indium layer may be changed stepwise as shown in FIG. 8. Further, as shown in FIG. 9, a projection may be formed in a part. The projection functions to collect the fused indium and prevent from exuding from a side (Jpn. Pat. Appln. KOKAI Publication No. 2002-184329).

Namely, the indium fusing method is not limited to the electrical heating described herein. The indium application shape of the invention is also adoptable to a method of heating by deciding the indium fusing order by the heat capacity difference between a corner and a side, or when heating indium locally by high-frequency heating, infrared heating and laser heating. The indium application method of the invention may be adopted to sealing by fusing indium simply by heating, because a heat capacity difference occurs even a little. It is effective also in this case to provide the above-mentioned projection.

Further, in the above embodiments, the ratio of the width at a corner to a center of a side is set to 50-98%. This may be changed after the baking process. Further, if an indium application step comes after a baking step or no baking step is used, the cross section of indium may be gradually changed by changing the indium application thickness and the shape of cross section as well as changing the indium application width.

Further, in the above embodiments, the base layer is formed on the sealing surface, and the indium layer is formed on the base layer. The indium layer may be formed directly on the sealing surface without using the base layer. In this case, also, by forming the indium layer to have a width gradually decreasing from substantially the center of each side of the sealing surface to adjacent corners, the same effect as described above can be obtained.

Contrarily, in the above embodiments, the base layer 31 and indium layer 32 are formed and sealed only on the sealing surface 11a of the front side substrate 11. The base layer 31 and indium layer 32 may be formed and sealed on only the sealing surface 18a of the sidewall 18 or both of the sealing surface 11a of the front side substrate 11 and the sealing surface 18a of the sidewall 18.

The invention is not to be limited to the embodiments described herein, and may be modified within the scope of the invention. For example, the rear side substrate and sidewall may be sealed with a sealing layer fused into the base layer 31 and indium layer 32, as described herein. It is allowed to bend the peripheral edge of one of the front side substrate and rear side substrate, and to connect these substrates directly without using a sidewall.

In the embodiments described herein, a field emission type electron emitting element is used as an electron emitting element. An electron emitting element is not limited to this type. Other types such as a pn-type cold cathode element and a surface conduction type electron emitting element may be used. The invention is applicable also to a plasma display panel (PDP), electroluminescent (EL) or other image display units.

As the image display unit of the invention has the configuration and effects described herein, the peripheral edges can be easily and securely sealed without unnecessarily heating the rear side substrate and front side substrate.

What is claimed is:

1. An image display unit comprising:
a vacuum enclosure having a rear side substrate and a front side substrate which are opposed to each other and sealed in the peripheral edges by a sealing agent fused by an electric current; and
a plurality of image display elements provided inside the vacuum enclosure,
wherein the fusing agent is applied all around a circular sealing surface at the peripheral edge between the rear side substrate and front side substrate, an electrode for applying an electric current is connected, and the width of the part connected to the electrode is less than the widths of the other parts.

2. The image display unit according to claim 1, wherein the sealing surface has a substantially rectangular frame-like shape,
the electrode is connected to the sealing agent at four corners of the sealing surface, and
the sealing agent is applied to the sealing surface to have a width gradually decreasing from substantially the center of four sides of the sealing surface toward adjacent corners.

3. The image display unit according to claim 2, wherein the width of the sealing agent at the corners is 50-98% of the width at substantially the center of the side.

4. An image display unit comprising:
a vacuum enclosure having a rear side substrate and a front side substrate which are opposed to each other and sealed in the peripheral edges by a sealing agent fused by an electric current; and
a plurality of image display elements provided inside the vacuum enclosure,
wherein the fusing agent is applied all around a circular sealing surface at the peripheral edge between the rear side substrate and front side substrate, an electrode for applying an electric current is connected, and the cross section of the part connected to the electrode is narrower than the cross sections of the other parts.

5. The image display unit according to claim 4, wherein the sealing surface has a substantially rectangular frame-like shape,
the electrode is connected to the sealing agent at four corners of the sealing surface, and
the sealing agent is applied to the sealing surface to have a width gradually decreasing from substantially the center of four sides of the sealing surface toward adjacent corners.

6. The image display unit according to claim 5, wherein the cross section of the sealing agent at the corners is 50-98% of the cross section at substantially the center of the side.

7. An image display unit comprising:
a vacuum enclosure having a rear side substrate and a front side substrate which are opposed to each other and sealed in the peripheral edges by a sealing agent fused by an electric current;
a fluorescent screen which is formed on the inner surface of the front side substrate;
an electron emission source which is provided on the inner surface of the rear side substrate, emits an electron beam to the fluorescent screen, and lights the fluorescent screen,
wherein the fusing agent is applied all around a circular sealing surface at the peripheral edge between the rear side substrate and front side substrate, an electrode for applying an electric current is connected to at least two locations, and the width of the part connected to the electrode is less than the widths of the other parts.

8. An image display unit comprising:
a vacuum enclosure having a rear side substrate and a front side substrate which are opposed to each other and sealed in the peripheral edges by a sealing agent; and
a plurality of image display element provided inside the vacuum enclosure,
wherein the fusing agent is applied all around a circular sealing surface at the peripheral edge between the rear side substrate and front side substrate, and the cross section of the sealing agent at corners of the sealing surface is narrower than the cross sections in the other parts.

9. An image display unit comprising:
a vacuum enclosure having a rear side substrate and a front side substrate which are opposed to each other and sealed in the peripheral edge by a sealing agent; and
a plurality of image display elements provided inside the vacuum enclosure,
wherein the fusing agent is applied all around a circular sealing surface at the peripheral edge between the rear side substrate and front side substrate, and the width of the sealing agent at corners of the sealing surface is less than the widths in the other parts.

10. The image display unit according to one of claims 1 to 9, wherein the sealing agent is a metal with a low melting point including In, Ga, Bi, Sn, Pb and Sb, or an alloy including one of these metals with a low melting point.
